(19) United States
(12) Patent Application Publication
(10) Pub. No.: US 2015/0048318 A1
(43) Pub. Date: Feb. 19, 2015

(54) ORGANIC LIGHT-EMITTING DIODE (OLED) DISPLAY AND METHOD OF MANUFACTURING SAME

(71) Applicant: Samsung Display co., Ltd., Yongin-City (KR)

(72) Inventor: Jae-Hoon Kim, Yongin-City (KR)

(73) Assignee: Samsung Display Co., Ltd.t, Yongin-City (KR)

(21) Appl. No.: 14/108,714

(22) Filed: Dec. 17, 2013

(30) Foreign Application Priority Data
Aug. 13, 2013 (KR) 10-2013-0096188

(51) Int. Cl. H01L 27/32

(52) U.S. Cl. CPC H01L 27/326
USPC 257/40; 438/22

(57) ABSTRACT

An organic light-emitting diode (OLED) display is disclosed. In one aspect, the OLED display includes a substrate, a pixel electrode disposed on the substrate and a pixel defining layer which covers an edge of the pixel electrode and exposes a center portion of the pixel electrode. The OLED display also includes a plurality of fine patterns disposed on the center portion, wherein the fine patterns are formed of the same material as that of the pixel defining layer.

### CROSS-REFERENCE TO RELATED APPLICATIONS

This application claims the benefit of Korean Patent Application No. 10-2013-0096188, filed on Aug. 13, 2013, in the Korean Intellectual Property Office, the disclosure of which is incorporated herein in its entirety by reference.

### BACKGROUND

1. Field

The described technology generally relates to an organic light-emitting diode (OLED) display.

2. Description of the Related Technology

OLED displays have attracted attention as next-generation displays due to their favorable qualities, such as wide viewing angles, high contrast, and quick response speeds.

In general, OLED displays include a pixel defining layer which covers the edge of a pixel electrode and exposes a center portion of the pixel electrode. An intermediate layer including an emission layer is formed on the pixel electrode using a method, such as inkjet printing, nozzle printing, or the like.

### SUMMARY OF CERTAIN INVENTIVE ASPECTS

One inventive aspect is an OLED display including a substantially planarized thin film and a method of manufacturing the same by removing the non-uniformity of the thin film. However, the embodiments of the described technology are only illustrative and do not limit the scope of the described technology.

Another aspect is an OLED display including a substrate, a pixel electrode disposed on the substrate, a pixel defining layer which covers an edge of the pixel electrode and exposes a center portion of the pixel electrode, and a plurality of fine patterns which are disposed on the center portion of the pixel electrode, wherein the fine patterns are formed of the same material as that of the pixel defining layer.

The OLED display may further include an intermediate layer disposed on the pixel electrode, wherein the intermediate layer is formed using an inkjet printing process.

The fine patterns may have a substantially line shape.

The fine patterns may have a substantially dot shape.

Each of the fine patterns may have a width of about 10 μm or less and a height of about 0.2 μm or less.

The intermediate layer may substantially cover the fine patterns.

Another aspect is a method of manufacturing an OLED display including providing a substrate, forming a pixel electrode on the substrate, forming a pixel defining layer which covers the pixel electrode and exposes a center portion of the pixel electrode, and forming a plurality of fine patterns on the pixel electrode, wherein the fine patterns are formed of the same material as that of the pixel defining layer.

The method further includes forming an intermediate layer on the pixel electrode, wherein the forming of the intermediate layer includes forming the intermediate layer using an inkjet printing process.

The forming of the pixel defining layer and the forming of the fine patterns may be performed substantially simultaneously using a halftone mask.

The forming of the fine patterns may include forming the fine patterns to have a substantially line shape.

The forming of the fine patterns may include forming the fine patterns to have a substantially dot shape.

The forming of the intermediate layer may include forming the intermediate layer to substantially cover the fine patterns.

### BRIEF DESCRIPTION OF THE DRAWINGS

These and/or other aspects will become apparent and more readily appreciated from the following description of the embodiments, taken in conjunction with the accompanying drawings.

FIG. 1 is a schematic cross-sectional view of an OLED display according to an embodiment.

FIGS. 2 to 5 are schematic cross-sectional views illustrating a method of manufacturing an OLED display according to an embodiment.

FIGS. 6 and 7 are schematic top views of an OLED display according to embodiments.

FIG. 8 is a schematic cross-sectional view of an OLED display according to an embodiment.

### DETAILED DESCRIPTION OF CERTAIN INVENTIVE EMBODIMENTS

The standard organic light-emitting diode (OLED) display and a method of manufacturing the same can produce stains due to the non-uniformity of the thickness of the intermediate layer of the pixels of the OLED display. The long-term reliability of the standard OLED display panel can be lowered due to these non-uniform thicknesses as well as variations in current density for each area of an OLED.

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the described technology. The size of elements illustrated in the drawings may be exaggerated for convenience of explanation. In other words, since the size and thickness of components in the drawings may be exaggerated for convenience of explanation, the following embodiments are not limited thereto.

In the following examples, the x-axis, the y-axis and the z-axis are not limited to the three axes of the rectangular coordinate system and may be interpreted in a broader sense. For example, the x-axis, the y-axis, and the z-axis may be perpendicular to one another or may represent different directions that are not perpendicular to one another.

It will be understood that when a layer, region, or component is referred to as being “formed on,” another layer, region, or component, it can be directly or indirectly formed on the other layer, region, or component. That is, for example, intervening layers, regions, or components may be present.

As used herein, expressions such as “at least one of,” when preceding a list of elements, modify the entire list of elements and do not modify the individual elements of the list.

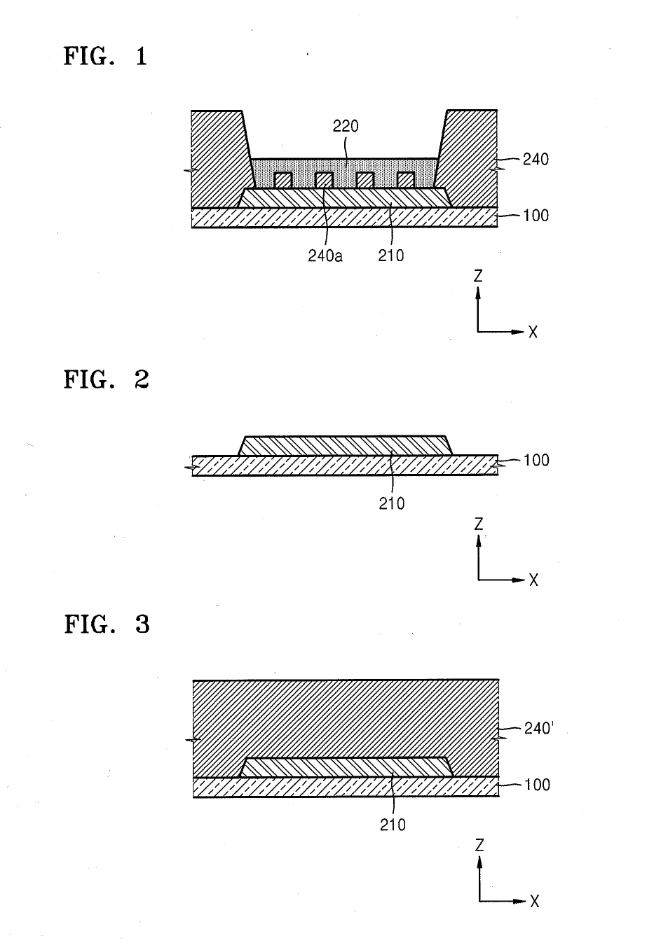

FIG. 1 is a schematic cross-sectional view of an OLED display according to an embodiment. As shown in FIG. 1, the OLED display may include a substrate 100, a pixel electrode 210, a pixel defining layer 240, an intermediate layer 220, and a plurality of fine patterns 240a.

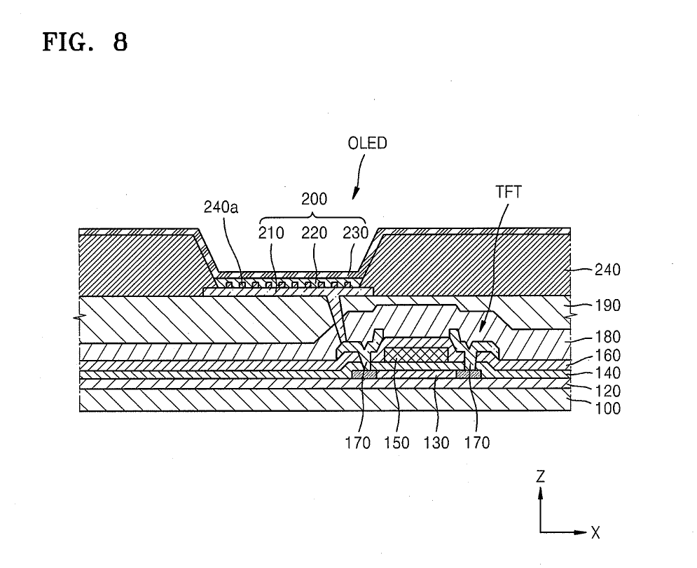

The pixel electrode 210 is disposed on the substrate 100. The substrate 100 may be formed of various materials, such as a glass material, a metallic material, or a plastic material. The disposition of the pixel electrode 210 on the substrate 100 includes not only the case where the pixel electrode 210 is directly disposed on the substrate 100 but also cases where various other layers are formed on the substrate 100 and then the pixel electrode 210 is disposed on the other layers. For example, a thin film transistor (TFT, see FIG. 8) may be disposed on the substrate 100, a planarization layer may cover the thin film transistor, and the pixel electrode 210 may be disposed on the planarization layer. FIG. 1 shows for convenience of description that the pixel electrode 210 is disposed directly on the substrate 100 and this configuration will be described hereinafter for convenience of description.

Although not shown in FIG. 1, the pixel electrode 210 may be electrically connected to the thin film transistor through contact with any one of a source or drain electrode of the thin film transistor. The pixel electrode 210 may be formed as a transparent (or translucent) electrode or a reflective electrode. When the pixel electrode 210 is formed as a transparent (or translucent) electrode, the pixel electrode 210 may be formed of, for example, an indium tin oxide (ITO), an indium zinc oxide (IZO), a zinc oxide (ZnO), an indium oxide (In₂O₃), an indium gallium oxide (IGO), or an aluminum zinc oxide (AZO). When the pixel electrode 210 is formed as a reflective electrode, the pixel electrode 210 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof and a layer formed of ITO, IZO, ZnO, In₂O₃, IGO, or AZO. However, the described technology is not limited thereto; the pixel electrode 210 may be formed of various materials and various modifications may be made such that the structure thereof is a single-layer structure or a multi-layer structure.

The pixel defining layer 240 which covers an edge of the pixel electrode 210 is disposed on the substrate 100 to expose a center portion of the pixel electrode 210. The pixel defining layer 240 defines a pixel with openings corresponding to respective sub-pixels, i.e., openings which expose a center portion of each pixel electrode 210. The pixel defining layer 240 may be formed of, for example, an organic material, such as polyimide or the like.

The fine patterns 240a are disposed on the pixel electrode 210. For example, the fine patterns 240a are disposed on the center portion of the pixel electrode 210 exposed by the pixel defining layer 240. The fine patterns 240a may include the same material as that of the pixel defining layer 240. The fine patterns 240a may also be formed of, for example, an organic material, such as polyimide or the like. In some embodiments, each of the fine patterns 240a has a width of about 10 μm or less and a height of about 0.2 μm or less. The fine patterns 240a may have various shapes, such as a substantially line shape, a substantially dot shape, or the like.

The intermediate layer 220 is disposed on the pixel electrode 210 to substantially cover the fine patterns 240a. The intermediate layer 220 of an OLED (200, see FIG. 8) may include a low-molecular material or a high-molecular material. When the intermediate layer 220 includes a low-molecular material, the intermediate layer 220 may be formed by stacking a hole injection layer (HIL), a hole transport layer (HTL), an emission layer (EML), an electron transport layer (ETL), an electron injection layer (EIL), and the like in a single or composite structure. The organic materials used to form the intermediate layer 220 may include at least one of copper phthalocyanine (CuPc), N, N′-di(naphthalene-1-yl)-N, N′-diphenyl-benzidine (NPB), tris-8-hydroxyquinoline aluminum (Alq₃), or other various materials.

When the intermediate layer 220 includes a high-molecular material, the intermediate layer 220 may have a structure including the HTL and the EML. In this case, poly(3,4)-ethylenedioxythiophene (PEDOT) may be used as the HTL, and a high-molecular organic material, such as polyphenylene vinylenes (PPVs), polyfluorenes, or the like, may be used as the EML.

The intermediate layer 220 is not limited to the above described structures and the structure thereof may be varied according to the design requirements.

The intermediate layer 220 is disposed on the pixel electrode 210. The intermediate layer 220 may be formed using inkjet printing, and in this case, the intermediate layer 220 may be disposed to substantially cover the fine patterns 240a. Since the intermediate layer 220 is disposed on the pixel electrode 210 on which the fine patterns 240a are disposed, the intermediate layer 220 may be substantially uniformly formed.

If the fine patterns 240a are not provided, the thickness of the intermediate layer 220 disposed in each pixel is not uniform, and accordingly, the brightness in each pixel may be non-uniform, thereby causing the quality of the OLED display to suffer. However, according to at least one embodiment, the fine patterns 240a are formed of the same material as that of the pixel defining layer 240 and are disposed on the pixel electrode 210 in a pixel area defined by the pixel defining layer 240. Consequently, ink forming the intermediate layer 220 can be substantially uniformly spread between and along the fine patterns 240a by means of capillary action or the like. Accordingly, the uniformity of the intermediate layer 220 may be dramatically increased, and thus, the intermediate layer 220 may be readily formed as a substantially uniform thin film.

Although the configuration of an OLED display has been described, the described technology is not limited thereto. For example, the described technology may also include a method of manufacturing an OLED display.

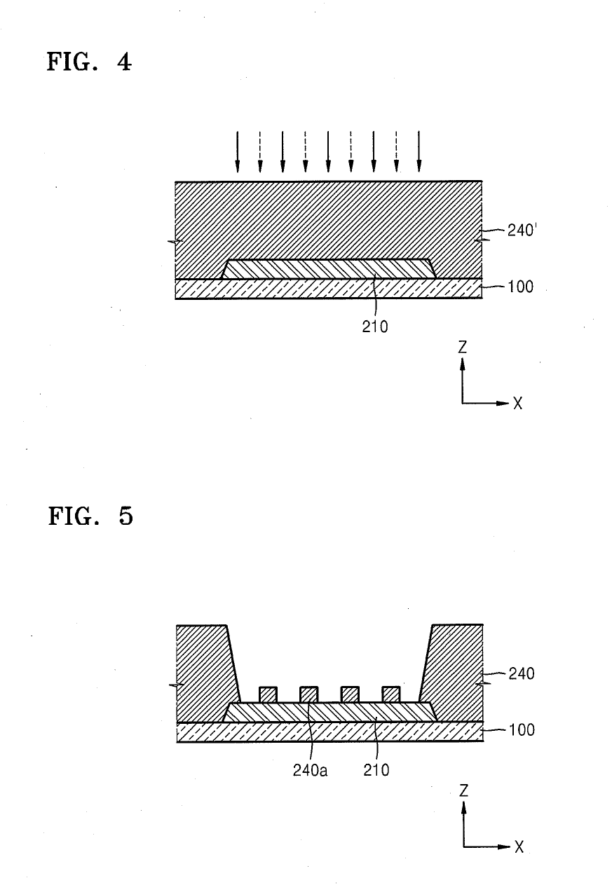

FIGS. 2 to 5 are schematic cross-sectional views illustrating a method of manufacturing an OLED display according to an embodiment.

First, as shown in FIG. 2, after preparing the substrate 100, the pixel electrode 210 is formed on the substrate 100. The substrate 100 may be formed of various materials, such as a glass material, a metallic material, a plastic material, or the like.

Although not shown in FIG. 2, the pixel electrode 210 may be electrically connected to a thin film transistor through contact with any one of a source or drain electrode of the thin film transistor. The pixel electrode 210 may be formed as a transparent (or translucent) electrode or a reflective electrode. When the pixel electrode 210 is formed as a transparent (or translucent) electrode, the pixel electrode 210 may be formed of, for example, ITO, IZO, ZnO, In₂O₃, IGO, or AZO. When the pixel electrode 210 is formed as a reflective electrode, the pixel electrode 210 may include a reflective layer formed of Ag, Mg, Al, Pt, Pd, Au, Ni, Nd, Ir, Cr, or a compound thereof and a layer formed of ITO, IZO, ZnO, In₂O₃, IGO, or AZO. However, the described technology is not limited thereto; the pixel electrode 210 may be formed of various materials and various modifications may be made such that the structure thereof is a single-layer structure or a multi-layer structure.

Thereafter, as shown in FIG. 3, a photoresist layer 240′ is coated on the pixel electrode 210 to form the pixel defining layer 240 on the pixel electrode 210. The pixel defining layer 240 defines a pixel with openings corresponding to respective sub-pixels, i.e., openings which expose a center portion of each pixel electrode 210. The photoresist layer 240′ for forming the pixel defining layer 240 may be formed of, for example, an organic material, such as polyimide or the like.

After coating the photoresist layer 240′ on the pixel electrode 210 as shown in FIG. 4, the pixel defining layer 240 may be formed using a halftone mask. Referring to FIG. 5, when the pixel defining layer 240 is formed, the fine patterns 240a are substantially simultaneously formed on a center portion of the pixel electrode 210 exposed by the pixel defining layer 240.

When the pixel defining layer 240 is formed using a halftone mask, the photoresist layer 240′ may be formed with a height difference. Thus, when the fine patterns 240a are to be formed on a partial area of the pixel electrode 210, the pixel defining layer 240 and the fine patterns 240a may be substantially simultaneously formed on the pixel electrode 210 by exposing the center portion of the pixel electrode 210 so that the partial area is exposed to less light than the exposed portion of the pixel electrode 210 by using the halftone mask. Thus, the fine patterns 240a may also include the same material as that of the pixel defining layer 240 and may be formed of, for example, an organic material, such as polyimide or the like, like the pixel defining layer 240. The fine patterns 240a may have various shapes, such as a substantially line shape, a substantially dot shape, or the like.

After forming the pixel defining layer 240, which exposes the center portion of the pixel electrode 210, and forming the fine patterns 240a on the center portion of the pixel electrode 210 exposed by the pixel defining layer 240 as described above, the intermediate layer 220 is formed to substantially cover the fine patterns 240a.

The intermediate layer 220 of an OLED (200, referring to FIG. 8) may include a low-molecular material or a high-molecular material. When the intermediate layer 220 includes a low-molecular material, the intermediate layer 220 may be formed by stacking an HIL, an HTL, an EML, an ETL, an EIL, and the like in a single or composite structure. When the intermediate layer 220 includes a high-molecular material, the intermediate layer 220 may have a structure including the HTL and the EML.

The intermediate layer 220 is not limited to the above description and may have various structures.

The intermediate layer 220 is disposed on the pixel electrode 210. The intermediate layer 220 may be formed using inkjet printing, and in this case, the intermediate layer 220 may be disposed to substantially cover the fine patterns 240a. In detail, the HIL may be disposed to substantially cover the fine patterns 240a, and thereafter, the HTL, the EML, the ETL, the EIL, and the like may be disposed on the HIL and substantially cover the fine patterns 240a.

If the fine patterns 240a are not provided, the thickness of the intermediate layer 220 disposed in each pixel is not uniform, and accordingly, the brightness in each pixel may be non-uniform, thereby causing the quality of the OLED display to suffer. However, according to at least one embodiment, the fine patterns 240a are formed of the same material as that of the pixel defining layer 240 and are disposed on the pixel electrode 210 in a pixel area defined by the pixel defining layer 240. Consequently, ink forming the intermediate layer 220 may be substantially uniformly spread between and along the fine patterns 240a by means of capillary action or the like. Accordingly, the uniformity of the intermediate layer 220 may be dramatically increased, and thus, the intermediate layer 220 may be readily formed as a substantially uniform thin film.

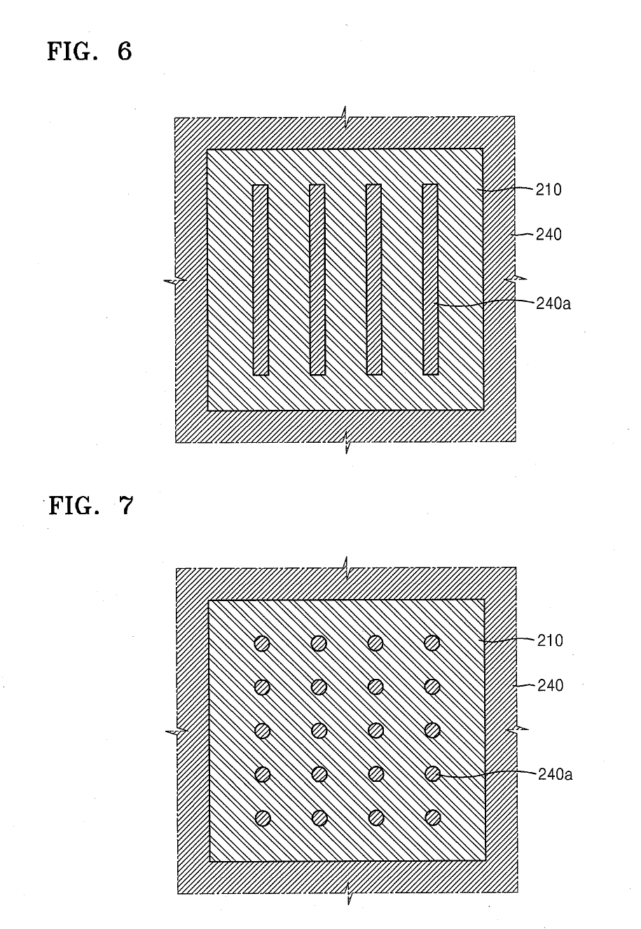

FIGS. 6 and 7 are schematic top views of an OLED display according to embodiments. As described above, the fine patterns 240a may be formed on the pixel electrode 210 to have various shapes, i.e., formed to have a substantially line shape as shown in FIG. 6 or to have a substantially dot shape as shown in FIG. 7. However, the shapes of the fine patterns 240a are not limited thereto and may be modified to have various other shapes. The thin film of the intermediate layer 220 may be substantially uniformly formed by evenly coating the intermediate layer 220 between the fine patterns 240a.

Although only a portion of the pixel electrode 210 of the OLED display has been described, the OLED display according to an embodiment may have the lower structure illustrated in FIG. 8.

As shown in FIG. 8, the OLED display according to an embodiment includes a thin film transistor TFT disposed on the substrate 100 and an OLED 200 electrically connected to the thin film transistor TFT. The thin film transistor TFT includes a semiconductor layer 130, which includes amorphous silicon, polycrystalline silicon, or an organic semiconductor material, a gate electrode 150, and source and drain electrodes 170.

A buffer layer 120 formed of silicon oxide, silicon nitride, or the like may be disposed on the substrate 100 to substantially planarize the surface of the substrate 100 or to substantially prevent the infiltration of impurities into the semiconductor layer 130 and the semiconductor layer 130 may be disposed on the buffer layer 120.

The gate electrode 150 and the source and drain electrodes 170 may be formed of various materials. The material of the gate electrode 150 may be selected in consideration of the adherence to an adjacent layer, the surface planarization of a layer to be stacked thereon, processability, and the like, and the material of the source and drain electrodes 170 may be selected in consideration of the conductivity thereof and the like. For example, the gate electrode 150 and the source and drain electrodes 170 may be formed as a single layer or multiple layers of at least one of Al, Pt, Pd, Ag, Mg, Au, Ni, Nd, Ir, Cr, lithium (Li), calcium (Ca), molybdenum (Mo), titanium (Ti), tungsten (W), or copper (Cu).

A gate insulating layer 140 is interposed between the gate electrode 150 and the semiconductor layer 130 to electrically insulate the semiconductor layer 130 from the gate electrode 150. An interlayer insulating layer 160 is interposed between the gate electrode 150 and each of the source and drain electrodes 170. The gate insulating layer 140 and the interlayer insulating layer 160 may be formed as a single layer or multiple layers of a material, such as silicon oxide, silicon nitride, or the like.

A protective layer 180 which covers the thin film transistor TFT may be disposed to protect the thin film transistor TFT. The protective layer 180 may be formed of, for example, an inorganic material, such as silicon oxide, silicon nitride, silicon oxynitride, or the like. Although the protective layer 180 is shown as a single layer in FIG. 8, various modifications may be made such that the protective layer 180 has a multi-layer structure.

A planarization layer 190 may be disposed on the protective layer 180 according to the design requirements. For example, when the OLED 200 is disposed on the thin film transistor TFT as shown in FIG. 8, the planarization layer 190 may be disposed to substantially planarize the upper surface of the protective layer 180 covering the thin film transistor TFT. The planarization layer 190 may be formed of, for example, an acrylic organic material, benzocyclobutene (BCB), or the like. Although the planarization layer 190 is shown as a single layer in FIG. 8, various modifications may be made such that the planarization layer 190 has a multi-layer structure.

The OLED 200 having the pixel electrode 210, an opposite electrode 230, and the intermediate layer 220 interposed therebetween and including the EML is disposed on the planarization layer 190 of the substrate 100.

The protective layer 180 and the planarization layer 190 include an opening which exposes at least one of the source and drain electrodes 170 of the thin film transistor TFT. The pixel electrode 210 is disposed on the planarization layer 190 and is electrically connected to the thin film transistor TFT through contract with any one of the source and drain electrodes 170 through the opening.

The pixel defining layer 240 is disposed on the planarization layer 190. The pixel defining layer 240 defines a pixel with openings corresponding to respective sub-pixels, i.e., openings which expose a center portion of each pixel electrode 210. In addition, in the embodiment of FIG. 8, the pixel defining layer 240 substantially prevents a short circuit between an end of the pixel electrode 210 and the opposite electrode 230 by increasing the distance therebetween. The pixel defining layer 240 may be formed of, for example, an organic material, such as polyimide or the like.

The fine patterns 240a including the same material as that of the pixel defining layer 240 are disposed on a center portion of the pixel electrode exposed by the pixel defining layer 240. As described above, the fine patterns 240a may have various shapes, such as a substantially line shape, a substantially dot shape, or the like, and the fine patterns 240a may be substantially simultaneously formed using a halftone mask when the pixel defining layer 240 is formed. As a result, since the fine patterns 240a are provided on the pixel electrode 210, the intermediate layer 220 disposed on the pixel electrode 210 on which the fine patterns 240a are disposed may be substantially uniformly formed.

The intermediate layer 220 of the OLED 200 may include a low-molecular material or a high-molecular material. When the intermediate layer 220 includes a low-molecular material, the intermediate layer 220 may be formed by stacking an HIL, an HTL, an EML, an ETL, an EIL, and the like in a single or composite structure. When the intermediate layer 220 includes a high-molecular material, the intermediate layer 220 may have a structure including the HTL and the EML.

The intermediate layer 220 is not limited to the above description and may have various other structures.

The opposite electrode 230 may be disposed to correspond to the whole surface of the substrate 100 as shown in FIG. 8. That is, the opposite electrode 230 may be formed commonly for a plurality of OLEDs 200 and may correspond to a plurality of pixel electrodes 210. The opposite electrode 230 may be formed as a transparent (or translucent) electrode or a reflective electrode. When the opposite electrode 230 is formed as a transparent (or translucent) electrode, the opposite electrode 230 may include a layer formed of a metal having a small work function, i.e., Li, Ca, lithium fluoride (LiF)/Ca, LiF/Al, Al, Ag, or Mg, or a compound thereof and a transparent (or translucent) conductive layer formed of ITO, IZO, ZnO, In₂O₃, or the like. When the opposite electrode 230 is formed as a reflective electrode, the opposite electrode 230 may include a layer formed of Li, Ca, LiF/Ca, LiF/Al, Al, Ag, Mg, or a compound thereof. The structure and material of the opposite electrode 230 are not limited thereto, and various modifications may be made.

According to at least one embodiment, the fine patterns 240a are disposed on the pixel electrode 210. Ink forming the intermediate layer 220 can be substantially uniformly spread between and along the fine patterns 240a by means of capillary action or the like. Accordingly, the uniformity of the intermediate layer 220 may be dramatically increased, and thus, the intermediate layer 220 may be readily formed as a substantially uniform thin film.

As described above, according to at least one embodiment, an OLED display including a substantially planarized thin film and a method of manufacturing the same by removing the non-uniformity of the thin film are disclosed. However, the scope of the described technology is not limited due to the effects thereof.

It should be understood that the exemplary embodiments described herein should be considered in a descriptive sense only and not for purposes of limitation. Descriptions of features or aspects within each embodiment should typically be considered as available for other similar features or aspects in other embodiments.

While one or more embodiment of the described technology have been described with reference to the figures, it will be understood by those of ordinary skill in the art that various changes in form and details may be made therein without departing from the spirit and scope of the present invention as defined by the following claims.

What is claimed is:

1. An organic light-emitting diode (OLED) display, comprising:
a substrate;
a pixel electrode formed over the substrate;
a pixel defining layer i) covering an edge of the pixel electrode and ii) exposing a center portion of the pixel electrode; and
a plurality of fine patterns i) formed over the center portion and ii) include the same material as that of the pixel defining layer.

2. The OLED display of claim 1, further comprising an intermediate layer formed over the pixel electrode.

3. The OLED display of claim 1, wherein the fine patterns have a substantially line shape.

4. The OLED display of claim 1, wherein the fine patterns have a substantially dot shape.

5. The OLED display of claim 1, wherein the width of each of the fine patterns is about 10 μm or less and wherein the height of each fine pattern is about 0.2 μm or less.

6. The OLED display of claim 1, further comprising an intermediate layer formed over the pixel electrode, wherein the intermediate layer substantially covers the fine patterns.

7. A method of manufacturing an organic light-emitting diode (OLED) display, comprising:
providing a substrate;
forming a pixel electrode over the substrate;
forming a pixel defining layer i) covering an edge of the pixel electrode and ii) exposing a center portion of the pixel electrode; and
forming a plurality of fine patterns over the center portion, wherein the fine patterns include the same material as that of the pixel defining layer.

8. The method of claim 7, further comprising forming an intermediate layer over the pixel electrode, wherein the intermediate layer is formed by an inkjet printing process.

9. The method of claim 7, wherein the forming of the pixel defining layer and the forming of the fine patterns are performed substantially simultaneously using a halftone mask.

10. The method of claim 7, wherein the forming of the fine patterns comprises forming the fine patterns to have a substantially line shape.

11. The method of claim 7, wherein the forming of the fine patterns comprises forming the fine patterns to have a substantially dot shape.

12. The method of claim 7, further comprising forming an intermediate layer over the pixel electrode to substantially cover the fine patterns.

13. An organic light-emitting diode (OLED) display, comprising:
a pixel electrode including a center portion;
a plurality of fine patterns formed over the center portion; and
an intermediate layer formed over the pixel electrode and substantially covering the fine patterns.

14. The OLED display of claim 13, further comprising a pixel defining layer i) covering an edge of the pixel electrode and ii) exposing the center portion.

15. The OLED display of claim 14, wherein the fine patterns are formed of the same material as that of the pixel defining layer.

16. The OLED display of claim 13, wherein the fine patterns have a substantially line shape.

17. The OLED display of claim 13, wherein the fine patterns have a substantially dot shape.

18. The OLED display of claim 13, further comprising a thin film transistor electrically connected to the pixel electrode.

19. The OLED display of claim 13, wherein the width of each of the fine patterns is about 10 μm or less.

20. The OLED display of claim 13, wherein the height of each of the fine patterns is about 0.2 μm or less.
